(19) United States
(12) Patent Application Publication
(10) Pub. No.: US 2025/0004196 A1
(43) Pub. Date: Jan. 2, 2025

(54) PHOTONIC-ELECTRONIC INTEGRATED-CIRCUIT CHIP AND PROCESS FOR FABRICATING SAME

(71) Applicant: Soitec, BERNIN (FR)

(72) Inventors: Ionut Radu, Bernin (FR); Christophe Maleville, Bernin (FR)

(21) Appl. No.: 18/702,411

(22) PCT Filed: Oct. 21, 2022
(86) PCT No.: PCT/FR2022/051998

§ 371 Date: Apr. 18, 2024

(30) Foreign Application Priority Data
Oct. 22, 2021 (FR) 2111256

(51) Int. Cl. G02B 6/12; G02B 6/13

(52) U.S. Cl. CPC G02B 6/12002; G02B 6/131

(57) ABSTRACT

A photonic-electronic integrated-circuit chip is formed on a semiconductor-on-insulator substrate. The silicon-on-insulator substrate has an embedded dielectric layer and an active layer of semiconductor material. The chip includes an electronic circuit portion and a photonic interconnection interface of the electronic circuit portion which are co-integrated in the active layer. The electronic circuit portion is formed in an active layer region, the thickness of which is greater than the thickness of an active layer region in which the photonic interface is formed.

### CROSS REFERENCE TO RELATED APPLICATIONS

This application is a national phase entry under 35 U.S.C. § 371 of International Patent Application PCT/FR2022/051998, filed Oct. 21, 2022, designating the United States of America and published as International Patent Publication WO 2023/067287 A1 on Apr. 27, 2023, which claims the benefit under Article 8 of the Patent Cooperation Treaty to French Patent Application Serial No. FR2111256, filed Oct. 22, 2021.

### TECHNICAL FIELD

The field of the invention is that of integrated circuits, more specifically that of photonic-electronic integrated circuits comprising electronic and photonic portions on the same chip.

### BACKGROUND

Heterogeneous computing involves various electronic circuits, such as central processing units (CPUs), graphic processing units (GPUs), field programmable gate arrays (FPGAs), neural network accelerators and shared memory resources.

These electronic circuits are generally connected together using metal wires/connectors in order to form a multi-core processing unit achieving the desired computing power. However, this type of assembly limits the bandwidth and the power density.

Photonics constitutes a promising technology for providing intra- or inter-chip optical communications that can overcome the limitations of electrical interconnections.

2.5D- or 3D-integration thus allows an electronic circuit portion to be combined with a photonic interconnection interface. As such integration requires photonic interposers and copper vertical interconnections, the aforementioned limitations nevertheless cannot be fully overcome.

For this reason, combining electronics and photonics on the same chip is desired, even though such a combination proves to be difficult due to the conflicting requirements, in particular, in terms of manufacturing, of each of these technologies.

Thus, for example, the article by Sun C., Wade M., Lee Y. et al., entitled “Single-chip microprocessor that communicates directly using light,” Nature 528, 534-538 (2015) is known that describes a solution for co-integrating an electronic circuit on the same silicon-on-insulator (SOI) substrate with optical devices providing interconnection functions for the electronic circuit by means of optical paths.

This solution involves providing an SOI substrate that comprises a thin surface layer of silicon separated from a supporting substrate by an embedded oxide layer and structuring the thin surface layer of silicon in order to form both the body of the electronic transistors and the core of the optical waveguides. However, with the embedded oxide layer of the SOI substrate being thin (<200 nm), light propagating in the waveguides is susceptible to evanescently escaping into the support substrate, which can lead to high losses in the waveguides. In order to address this issue, this solution recommends proceeding with selective removal of the substrate following the electrical encapsulation of the chip in order to eliminate the support substrate under the regions comprising optical devices by etching.

However, this selective post-encapsulation removal is difficult to achieve, making this solution difficult to industrialize.

### BRIEF SUMMARY

The aim of the present disclosure is to propose a simpler solution for monolithic integration on the same substrate of an electronic circuit portion with a photonic interconnection interface providing intra- or inter-chip optical communication for the electronic circuit portion with a minimal number of metal interconnections.

To this end, the present disclosure proposes, according to a first aspect, a photonic-electronic integrated circuit chip formed on a semiconductor-on-insulator substrate, which silicon-on-insulator substrate comprises an embedded dielectric layer and an active layer of semiconductor material. The chip comprises an electronic circuit portion and a photonic interconnection interface of the electronic circuit portion co-integrated in the active layer. The electronic circuit portion is formed in an active layer region, the thickness of which is greater than the thickness of an active layer region in which the photonic interface is formed.

Some preferred but non-limiting aspects of this chip are as follows:
the active layer region in which the photonic interface is formed is sandwiched between the embedded dielectric layer and a surface dielectric region and the active layer region in which the electronic circuit portion is formed is devoid of a surface dielectric layer;
the thickness of the active layer region in which the electronic circuit portion is formed is greater than 0.2 μm, preferably greater than 0.5 μm;
the thickness of the active layer region in which the photonic interface is formed ranges between 0.2 μm and 0.5 μm;
the thickness of the embedded dielectric layer is greater than 1 μm, preferably greater than 2 μm;
the photonic interface comprises at least one waveguide;
the photonic interface further comprises an active photonic circuit portion;
the electronic circuit portion comprises a transistor logic module;
the transistors are of the FinFET or GAAFET type.

According to a second aspect, the present disclosure relates to a semiconductor-on-insulator substrate comprising a support substrate, an embedded dielectric layer and an active layer of semiconductor material separated from the support substrate by the embedded oxide layer. An active layer region intended for forming an electronic circuit portion is thicker than the thickness of an active layer region intended for forming a photonic interconnection interface of the electronic circuit portion.

According to a third aspect, the present disclosure relates to a method for manufacturing a semiconductor-on-insulator substrate according to the second aspect, comprising transferring the active layer from a donor substrate to the support substrate, the transferring comprising bonding the donor substrate and the support substrate with an oxide layer at the bonding interface.

Some preferred but non-limiting aspects of the method are as follows:
it further comprises localized etching of the transferred active layer in order to form the active layer region intended for forming the photonic interconnection interface;
it further comprises forming a dielectric layer on the surface of the active layer region intended for forming the photonic interconnection interface;
it further comprises forming the active layer region intended for forming the electronic circuit portion by means of localized epitaxial growth;
the formation of the active layer region intended for forming the electronic circuit portion is preceded by steps of oxidizing the transferred active layer in order to form a dielectric layer and localized removal of the dielectric layer, with the remaining dielectric layer after localized removal acting as a mask for the localized epitaxial growth;
it comprises forming a dielectric layer on the surface of an active layer region that has not been subject to localized epitaxial growth.

According to a fourth aspect, the present disclosure relates to a method for manufacturing a photonic-electronic integrated circuit chip, comprising the following steps:
manufacturing a semiconductor-on-insulator substrate in accordance with the method according to the third aspect;
forming an electronic circuit portion in the active layer region intended for forming an electronic circuit portion;
forming a photonic interconnection interface in the active layer region intended for forming a photonic interconnection interface of the electronic circuit portion.

Manufacturing the semiconductor-on-insulator substrate comprises, before or after all or part of the formation of the photonic interconnection interface, forming a dielectric layer on the surface of the active layer region intended for forming the photonic interconnection interface.

### BRIEF DESCRIPTION OF THE DRAWINGS

Further aspects, aims, advantages and features of the invention will become more apparent from reading the following detailed description of preferred embodiments thereof, which are provided by way of a non-limiting example, and with reference to the accompanying drawings, in which:

FIG. 1 is a diagram of a photonic-electronic integrated circuit chip according to the present disclosure;

FIG. 2 is a schematic cross-sectional view of a single-crystal Si donor substrate;

FIG. 3 is a schematic cross-sectional view illustrating the formation of a dielectric layer on the surface of the single-crystal Si donor substrate;

FIG. 4 is a schematic cross-sectional view illustrating the formation, by implanting ion species, of a plane of weakness in the donor substrate of FIG. 2 for defining an active layer of single-crystal Si to be transferred;

FIG. 5 is a schematic cross-sectional view illustrating the assembly of the donor substrate of FIG. 3 and of a support substrate;

FIG. 6 is a schematic cross-sectional view illustrating the detachment of the donor substrate along the plane of weakness in order to transfer the single-crystal Si active layer onto the support substrate;

FIG. 7 is a schematic cross-sectional view illustrating localized etching of the single-crystal Si active layer following the detachment of FIG. 6;

FIG. 8 is a schematic cross-sectional view illustrating oxidation of the single-crystal Si active layer following the localized etching of FIG. 7;

FIG. 9 is a schematic cross-sectional view illustrating localized removal of the oxide layer formed by the oxidation of FIG. 8;

FIG. 10 is a schematic cross-sectional view illustrating oxidation of the single-crystal Si active layer following the detachment of FIG. 6;

FIG. 11 is a schematic cross-sectional view illustrating localized removal of the oxide layer formed by the oxidation of FIG. 10; and

FIG. 12 is a schematic cross-sectional view illustrating localized epitaxial growth using the oxide layer remaining, after the localized removal thereof of FIG. 11, as a mask.

### DETAILED DESCRIPTION

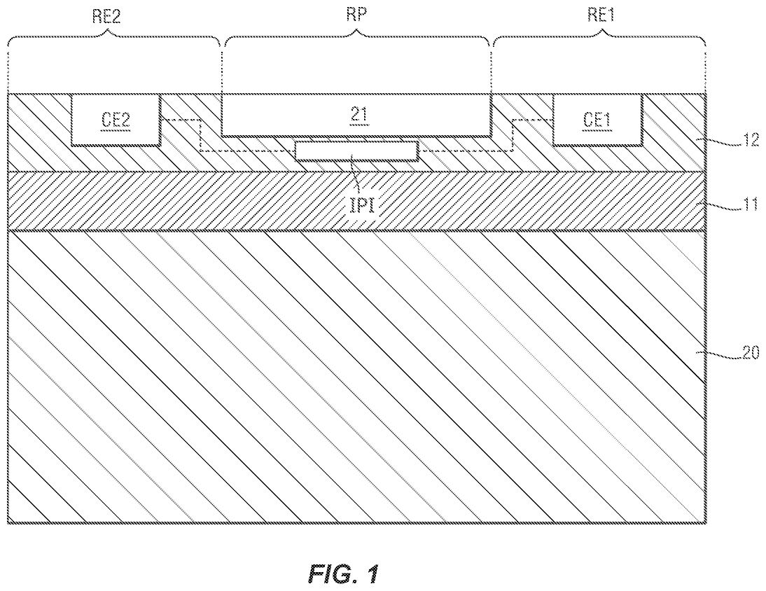

With reference to FIG. 1, the invention relates to a photonic-electronic integrated circuit chip formed on a semiconductor-on-insulator substrate, which silicon-on-insulator substrate comprises an embedded dielectric layer 11 and an active layer 12 of semiconductor material, for example, single-crystal silicon. The embedded dielectric layer 11 typically separates the active layer of semiconductor material 12 from a support substrate 20.

The chip according to the present disclosure comprises, co-integrated in the active layer 12, an electronic circuit portion CE1, CE2 and a photonic interconnection interface IPI of the electronic circuit portion. In the example of FIG. 1, the photonic interconnection interface IPI acts as an intra-chip interface interconnecting two electronic circuit portions CE1 and CE2. The present disclosure also extends to a photonic interconnection interface IPI acting as an inter-chip interface interconnecting an electronic circuit portion integrated in the chip with an electronic circuit portion integrated in another chip.

Each electronic circuit portion CE1, CE2 can comprise a transistor logic module, for example, based on FinFET (“Fin Field-Effect Transistor”) or GAAFET (“Gate-All-Around Field-Effect Transistor”) type transistors.

The photonic interface IPI typically comprises at least one waveguide. It can also comprise an active photonic circuit portion, such as an electro-optical modulator or even a laser transferred on the interface IPI, for example.

According to the present disclosure, the electronic circuit portion CE1, CE2 is formed in an active layer region RE1, RE2, the thickness of which is greater than the thickness of an active layer region RP in which the photonic interface IPI is formed.

The thickness of the active layer region RE1, RE2 in which the electronic circuit portion CE1, CE2 is formed can be greater than 0.2 μm, preferably greater than 0.5 μm.

The thickness of the active layer region RP in which the photonic interface IPI is formed for its part can range between 0.2 μm and 0.5 μm.

The embedded dielectric layer can be more than 200 nm thick, for example, more than 1 μm thick, preferably more than 2 μm thick.

In a preferred embodiment, the active layer region RP in which the photonic interface IPI is formed is sandwiched between the embedded dielectric layer 11 and a surface dielectric region 21 and the active layer region RE1, RE2 in which the electronic circuit portion CE1, CE2 is formed is devoid of a surface dielectric layer. The thickness of the surface dielectric region 21 typically corresponds to the difference in thickness between the active layer region RP in which the photonic interface IPI is formed and the active layer region RE1, RE2 in which the electronic circuit portion CE1, CE2 is formed.

The chip, according to the present disclosure, is thus manufactured on a semiconductor-on-insulator substrate with a thick embedded oxide layer. The active layer region intended for forming the electronic circuit portion is thick enough to prevent the operation of this portion from being adversely affected by the embedded oxide layer. Furthermore, the active layer region intended for forming the photonic interconnection interface for its part exhibits a thickness and optical confinement that are optimized for forming quality optical interconnections in a horizontal plane.

According to another aspect, the present disclosure relates to a semiconductor-on-insulator substrate comprising an embedded dielectric layer 11 and an active layer 12 of semiconductor material. In this substrate, an active layer region RE1, RE2 intended for forming an electronic circuit portion CE1, CE2 is thicker than the thickness of an active layer region RP intended for forming a photonic interconnection interface IPI of the electronic circuit portion.

The present disclosure also relates to a method for manufacturing such a semiconductor-on-insulator substrate, with this method comprising transferring the active layer from a donor substrate to a support substrate. Such a transfer typically comprises bonding the donor substrate and the support substrate with an oxide layer at the bonding interface and can be performed in accordance with BESOI technology by thinning the rear face of the donor substrate, or in accordance with Smart Cut™ technology by detachment in the vicinity of a plane of weakness previously formed by implanting ion species into the donor substrate.

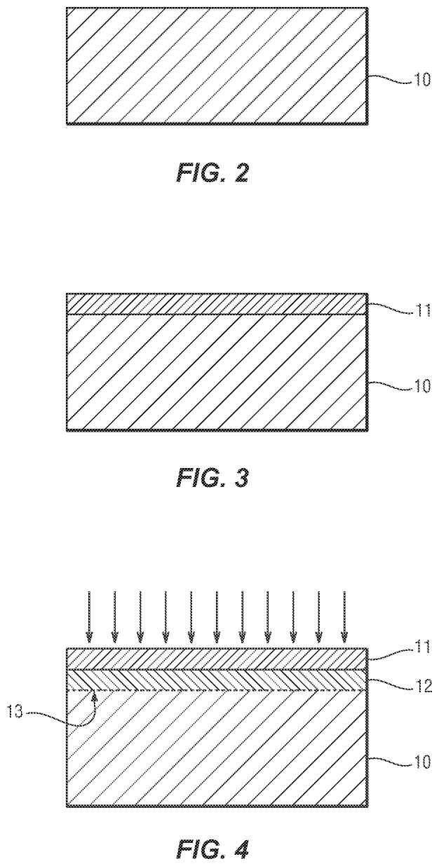

Various examples of such a manufacturing method using Smart Cut™ technology will be described hereafter. With reference to FIG. 2, such a method can begin by providing a donor substrate 10, at least a surface portion of which is made of semiconductor material. A bulk substrate 10 of single-crystal Si has been shown in the figures. With reference to FIG. 3, the method comprises a step of forming an oxide layer 11 on the donor substrate 10, with this oxide layer being intended to form all or part of the aforementioned embedded dielectric layer 11.

According to another embodiment, the method comprises a step of forming the oxide layer 11 on the support substrate 20.

With reference to FIG. 4, the method further comprises implanting ion species in the donor substrate 10 so as to form a plane of weakness 13 defining a single-crystal Si active layer 12 to be transferred. The implanted species typically comprise hydrogen and/or helium. A person skilled in the art will be able to define the required implantation dose and energy.

When the oxide layer is formed on the support substrate 20, due to the absence of such an oxide layer on the donor substrate, the plane of weakness 13 can be formed deeper into the donor substrate, which ultimately allows a thicker active layer 12 to be transferred.

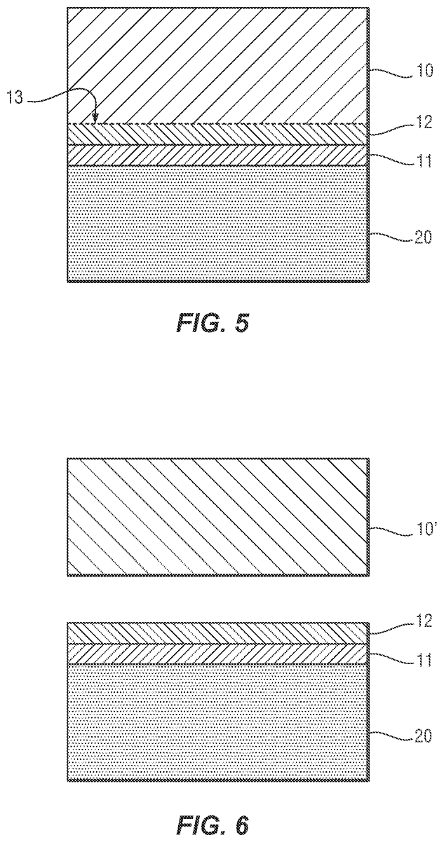

With reference to FIG. 5, the method comprises, after the implanting, bonding the donor substrate 10 and a support substrate 20. The bonding involves direct bonding obtained by molecular adhesion of the surfaces that are brought into contact. With reference to FIG. 6, the method then comprises detaching the donor substrate 10 along the plane of weakness 13 so as to transfer the single-crystal Si active layer 12 onto the support substrate 20. In a known manner, this detachment can be caused by a heat treatment, a mechanical action, or a combination of these means. The remainder 10′ of the donor substrate optionally can be recycled with a view to another use.

One or more finishing operations then can be applied to the transferred single-crystal Si active layer 12. It is possible, for example, for smoothing, cleaning, or even polishing, for example, Chemical Mechanical Polishing (CMP), to be carried out in order to remove the defects related to implanting ion species and to reduce the roughness of the transferred single-crystal Si active layer 12.

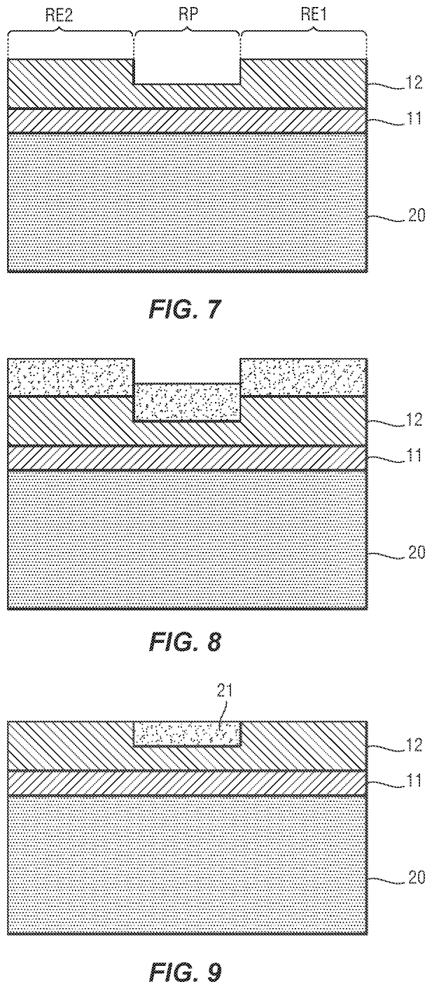

In one possible embodiment, the implanting energy is such that the thickness of the transferred active layer 12 is suitable for producing an electronic circuit portion, with this thickness being, for example, greater than 0.2 μm, preferably greater than 0.5 μm. In such an example, as shown in FIG. 7, the method can comprise localized etching of the transferred active layer 12 in order to form an active layer region RP intended for forming a photonic interconnection interface. An un-etched region for its part allows an active layer region RE1, RE2 to be formed that is intended for forming an electronic circuit portion. The method can continue with the formation of a dielectric layer 21 on the surface of the active layer region intended for forming the photonic interconnection interface. This formation can comprise, as shown in FIGS. 8 and 9, thermal oxidation of the active layer 12, followed by localized removal of the oxide layer thus formed in the one or more region(s) of the active layer intended for forming an electronic circuit portion. In an alternative embodiment, such formation can comprise localized oxidation of the active layer, carried out in the one or more region(s) of the active layer intended for the formation of a photonic interconnection interface by using a mask of the other regions of the active layer, for example, with a nitride-based mask.

In another alternative embodiment, following the localized etching illustrated in FIG. 7, the method can comprise forming all or part of the photonic interconnection interface prior to the formation of the dielectric layer 21. For example, the method can comprise shaping a waveguide in the etched region RP before proceeding with the formation of the dielectric layer 21 on the waveguide. This waveguide is thus well confined within the dielectric layer, thereby further minimizing optical losses.

In another possible embodiment, the implanting energy is such that the thickness of the transferred active layer 12 is not directly suitable for producing an electronic circuit portion. In such an example, the method comprises forming the active layer region intended for forming the electronic circuit portion by means of epitaxial growth.

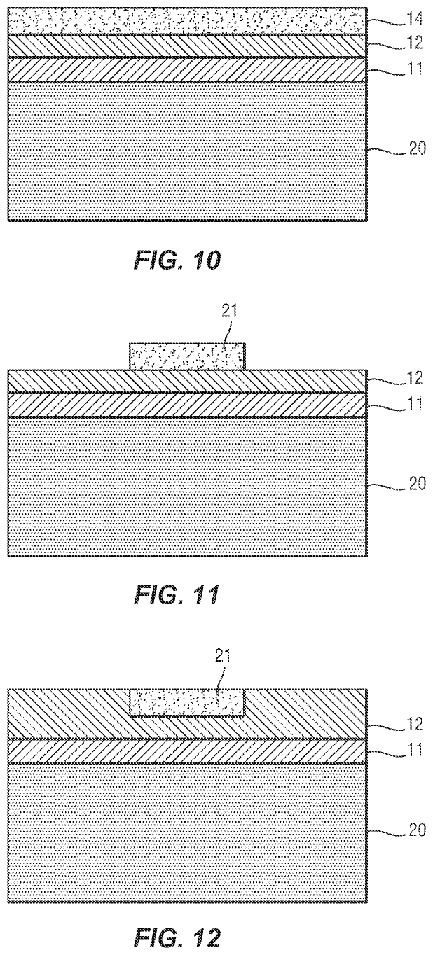

In a first variant of this other embodiment, the method comprises, following the detachment illustrated in FIG. 6, a step involving, as shown in FIG. 10, forming, for example, by means of thermal oxidation, a dielectric layer 14 on the transferred active layer 12, and then a step involving, as shown in FIG. 11, carrying out localized removal of the dielectric layer 14 in the one or more region(s) of the active layer intended for forming an electronic circuit portion, with the remaining dielectric forming the surface layer 21 covering the active layer region intended for forming a photonic interface. As shown in FIG. 12, localized epitaxial growth used to thicken the active layer in the one or more region(s) of the active layer intended for forming an electronic circuit portion is then carried out, with the dielectric layer 21 remaining after the localized removal thereof being able to act as a mask for the localized epitaxial growth.

In a second alternative embodiment, the formation of the active layer region intended for forming the electronic circuit portion comprises localized epitaxial growth, which is carried out immediately after the detachment shown in FIG. 6. This localized epitaxial growth is followed by oxidation for forming the surface layer 21 covering the active layer region intended for forming a photonic interface. This oxidation can be a localized oxidation for forming a dielectric layer on the surface of an active layer region not subject to localized epitaxial growth. Alternatively, it can involve full wafer oxidation, which is then followed by localized removal in order to leave only the surface layer 21 covering the active layer region intended for forming a photonic interface.

In a third alternative embodiment, full wafer epitaxial growth is carried out following the detachment illustrated in FIG. 6. This epitaxial growth is followed by localized etching and oxidation for forming the surface layer 21 covering the active layer region intended for forming a photonic interface.

The present disclosure also relates to a method for manufacturing a photonic-electronic integrated circuit chip as described above, in particular, with reference to FIG. 1. This method comprises the following steps:
manufacturing a semiconductor-on-insulator substrate in accordance with the method, various alternative embodiments of which have been disclosed above;
forming an electronic circuit portion in the active layer region intended for forming an electronic circuit portion;
forming a photonic interconnection interface in the active layer region intended for forming a photonic interconnection interface of the electronic circuit portion.

In this method, manufacturing the semiconductor-on-insulator substrate can comprise, before or after all or part of the formation of the photonic interconnection interface, forming the dielectric layer 21 on the surface of the active layer region intended for forming the photonic interconnection interface.

1. A Photonic-electronic integrated circuit chip formed on a semiconductor-on-insulator substrate, the semiconductor-on-insulator substrate having an embedded dielectric layer and an active layer of semiconductor material, the chip comprising an electronic circuit portion and a photonic interconnection interface of the electronic circuit portion co-integrated in the active layer, wherein the electronic circuit portion is formed in an active layer region, a thickness of which is greater than a thickness of an active layer region in which the photonic interface is formed.

2. The chip of claim 1, wherein the active layer region in which the photonic interface is formed is sandwiched between the embedded dielectric layer and a surface dielectric region, and the active layer region in which the electronic circuit portion is formed is devoid of a surface dielectric layer.

3. The chip of claim 1, wherein the thickness of the active layer region in which the electronic circuit portion is formed is greater than 0.2 μm.

4. The chip of claim 1, wherein the thickness of the active layer region in which the photonic interface is formed is between 0.2 μm and 0.5 μm.

5. The chip of claim 1, wherein a thickness of the embedded dielectric layer is greater than 1 μm.

6. The chip of claim 1, wherein the photonic interface comprises at least one waveguide.

7. The chip of claim 1, wherein the electronic circuit portion comprises a transistor logic module.

8. A semiconductor-on-insulator substrate comprising a support substrate, an embedded dielectric layer, and an active layer of semiconductor material separated from the support substrate by the embedded dielectric layer, wherein an active layer region intended for forming an electronic circuit portion is thicker than a thickness of an active layer region intended for forming a photonic interconnection interface of the electronic circuit portion.

9. A method for manufacturing a semiconductor-on-insulator substrate comprising a support substrate, an embedded dielectric layer, and an active layer of semiconductor material separated from the support substrate by the embedded dielectric layer, wherein an active layer region intended for forming an electronic circuit portion is thicker than a thickness of an active layer region intended for forming a photonic interconnection interface of the electronic circuit portion, the method comprising transferring the active layer from a donor substrate to the support substrate, the transferring comprising bonding the donor substrate and the support substrate with an oxide layer at the bonding interface.

10. The method of claim 9, further comprising localized etching of the transferred active layer to form the active layer region intended for forming the photonic interconnection interface.

11. The method of claim 10, further comprising forming a dielectric layer on a surface of the active layer region intended for forming the photonic interconnection interface.

12. The method of claim 9, further comprising forming the active layer region intended for forming the electronic circuit portion by localized epitaxial growth.

13. The method of claim 12, wherein the formation of the active layer region intended for forming the electronic circuit portion is preceded by oxidizing the transferred active layer to form a dielectric layer and localized removal of the dielectric layer, with the remaining dielectric layer after localized removal acts as a mask for the localized epitaxial growth.

14. The method of claim 12, further comprising forming a dielectric layer on a surface of an active layer region that has not been subjected to localized epitaxial growth.

15. A method for manufacturing a photonic-electronic integrated circuit chip, comprising:
manufacturing a semiconductor-on-insulator substrate in accordance with the method of claim 9;
forming an electronic circuit portion in the active layer region intended for forming an electronic circuit portion; and
forming a photonic interconnection interface in the active layer region intended for forming a photonic interconnection interface of the electronic circuit portion.

16. The method of claim 15, wherein manufacturing the semiconductor-on-insulator substrate comprises, before or after all or part of the formation of the photonic interconnection interface, forming a dielectric layer on the surface of the active layer region intended for forming the photonic interconnection interface.

17. The chip of claim 3, wherein the thickness of the active layer region in which the electronic circuit portion is formed is greater than 0.5 μm.

18. The chip of claim 5, wherein a thickness of the embedded dielectric layer is greater than 2 μm.

19. The chip of claim 6, wherein the photonic interface comprises an active photonic circuit portion.

20. The chip of claim 7, wherein the transistor logic module comprises FinFET or GAAFET transistors.
